(19) United States
(12) Patent Application Publication
(10) Pub. No.: US 2009/0139759 A1
(43) Pub. Date: Jun. 4, 2009

(54) LAMINATED CERAMIC ELECTRONIC COMPONENT AND MANUFACTURING METHOD THEREFOR

(75) Inventors: Mitsuru Ueda, Shiga-ken (JP); Masaharu Ikeda, Shiga-ken (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi, Kyoto-fu (JP)

(21) Appl. No.: 10/596,097

(22) PCT Filed: Nov. 24, 2005
(86) PCT No.: PCT/JP2005/021544

§ 371 Date: May 30, 2006

(30) Foreign Application Priority Data
Dec. 20, 2004 (JP) 2004-367863

(51) Int. Cl. H05K 1/11; B32B 38/14

(52) U.S. Cl. 174/262; 156/60

(57) ABSTRACT

A laminated ceramic electronic component includes a plurality of ceramic green sheets. In each of the ceramic green sheets, which are not backed with a carrier film, coil conductor patterns and lead-out electrodes are formed by a screen printing method and simultaneously a conductive paste is filled in holes for via holes to form via holes. The coil conductor patterns include first lands provided at one end of the coil conductor patterns so as to cover the via holes for connection between layers and second lands to be connected to the via holes provided at the other end of the conductive patterns. The second lands are larger in diameter than the first lands, such that the area of the second lands is about 1.10 to about 2.25 times as wide as the area of the first lands.

### BACKGROUND OF THE INVENTION

1. Field of the Invention

The present invention relates to a laminated ceramic electronic component, and more particularly, to a laminated ceramic electronic component, such as an inductor or an impedance element, and a manufacturing method therefor.

2. Description of the Related Art

A conventional laminated ceramic electronic component is described in Japanese Unexamined Patent Application Publication No. 2004-87596 (Patent Document 1). In this electronic component, a spiral coil includes ceramic sheets having coil-forming conductors provided therein that are laminated together, and a pad (land) disposed at an end portion of each coil-forming conductor that is connected in order through a via hole.

That is, as shown in FIG. 6, a coil-forming conductor 51 is formed on the surface of a ceramic sheet 50 by a screen printing method at a location at which a via hole is formed in the ceramic sheet 50, and at the same time, the via hole is filled with a conductive paste to form a via hole 60. The coil-forming conductor 51 includes a first land 51a at the location at which a via hole 60 for connection between layers and a second land 51b to be connected to the via hole 60.

When the conditions are set for screen printing the first land 51a formed at the location at which the via hole is provided or are set for the second land 51b at which no via hole is provided, there is a problem in that printing defects and insufficient filling are likely to occur at the other land.

For example, as shown in FIG. 7, when the penetration amount of conductive paste 55 in a screen printing plate 66 is increased such that the second land 51b does not have thin spots, the via hole is overfilled with the conductive paste 55 such that the conductive paste 55 protrudes from the back surface of the ceramic sheet. On the other hand, when the fill amount of conductive paste 55 is set for the via hole, thin spots are likely to occur in the second land 51b having no via hole. This is because the penetration amount of the conductive paste 55 through the screen printing plate 66 is different depending on whether or not the via hole exists even if the shape of the lands is the same.

In order to prevent the conductive paste 55 from protruding from the back surface of the ceramic sheet 50, as shown in FIG. 8, the ceramic sheet 50 may be backed with a carrier film 52. However, a new problem is created in that the use of the carrier film 52 increases the manufacturing cost.

### SUMMARY OF THE INVENTION

To overcome the problems described above, preferred embodiments of the present invention provide a laminated ceramic electronic component in which, without providing a carrier film, appropriate filling of the via hole and the prevention of thin spots in lands are provided and a manufacturing method therefor.

A laminated ceramic electronic component according to a preferred embodiment of the present invention includes a plurality of ceramic sheets, each having an internal conductor pattern including a first land at one end of the internal conductor pattern and a second land at the other end and having a hole of a via hole provided therein, the plurality of ceramic sheets being laminated to define a laminate. In the laminated ceramic electronic component, the hole for the via hole is filled with a conductive material, the internal conductor patterns disposed on different layers are electrically connected to each other through the via hole, the first land is arranged so as to cover the via hole and the first land provided in one ceramic sheet is electrically connected to the second land provided in another ceramic sheet through the via hole provided in the one ceramic sheet, and the second land is larger than the first land.

Preferably, the second land extends from a projection plane of the first land to a projection plane of the coil conductor pattern. Furthermore, the area of the second land is preferably about 1.10 to about 2.25 times as wide as the area of the first land.

A manufacturing method for a laminated ceramic electronic component according to another preferred embodiment of the present invention includes the steps of printing an internal conductor pattern having a first land at one end of the internal conductor pattern and a second land at the other end on the surface of a ceramic sheet having a hole for a via hole formed therein by using a conductive material such that the first land covers the via hole, filling the conductive material in the hole for the via hole, and laminating a plurality of ceramic sheets such that the first land provided in one ceramic sheet is electrically connected to the second land provided in another ceramic sheet through the via hole formed in the one ceramic sheet to obtain a laminate. In the manufacturing method for a laminated ceramic electronic component, the second land is larger than the first land.

Preferably, the internal conductor pattern is printed on a ceramic sheet having the via hole formed therein and the via hole be filled with a conductive material at the same time, providing a carrier film on the back surface of the ceramic sheet.

According to preferred embodiments of the present invention, since the shape of the second land connected to a via hole in which thin spots are likely to occur during screen printing is enlarged, the discharge amount of conductive paste for forming the second land increases and appropriate filling of the via hole and the prevention of thin spots in the second land are provided. As a result, a laminated ceramic electronic component in which the reliability and productivity are outstanding is obtained.

In particular, when the area of the second land is at least about 1.10 times as wide as the area of the first land, thin spots in the second land are effectively prevented to suppress the problem of electrostatic discharge and prevent lamination slippage. Furthermore, when the area of the second land is equal to or less than about 2.25 times as wide as the area of the first land, the reduction in the inductance value is suppressed.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is an exploded perspective view showing a preferred embodiment of a laminated ceramic electronic component according to the present invention.

FIG. 2 is a top view of an internal conductor pattern shown in FIG. 1.

FIG. 3 is a sectional view showing the essential component of lamination of the laminated ceramic electronic component shown in FIG. 1.

FIG. 4 is a perspective appearance of the laminated ceramic electronic component shown in FIG. 1.

FIG. 5 is a top view of a modified example of the internal conductor pattern shown in FIG. 1.

FIG. 6 is a top view showing an internal conductor pattern of a related laminated ceramic electronic component.

FIG. 7 is an illustration showing a manufacturing method for a related laminated ceramic electronic component.

FIG. 8 is an illustration showing another manufacturing method for a related laminated ceramic electronic component.

### DETAILED DESCRIPTION OF PREFERRED EMBODIMENTS

Hereinafter, preferred embodiments of a laminated ceramic electronic component and a manufacturing method therefor according to the present invention are described with reference to the accompanied drawings. In the following preferred embodiments, a laminated inductor is described as an example, but a laminated impedance element and a laminated LC composite component may be used instead.

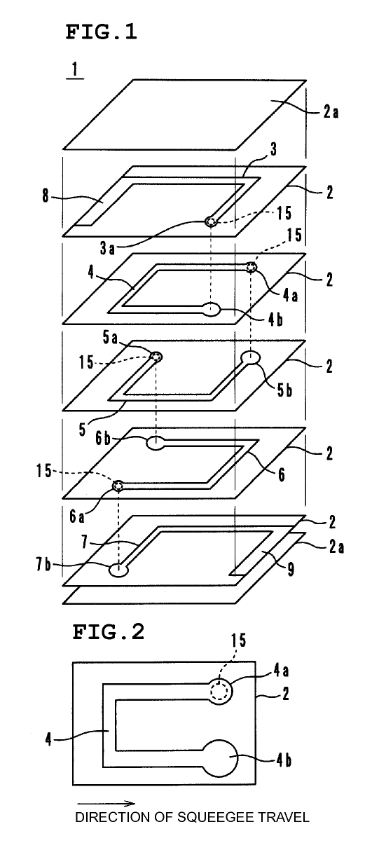

As shown in FIG. 1, a laminated inductor 1 includes ceramic green sheets 2 in which coil conductor patterns 3 to 7, lead-out electrodes 8 and 9, and via holes 15 are provided, and external ceramic green sheets 2a not having conductor patterns.

The ceramic green sheets 2 and 2a are produced by the following method. Various raw powders, such as raw ferrite powders NiO, CuO, ZnO, Fe₂O₃, etc., are wet-mixed by a ball mill or other suitable mixer, and dried by a spray dryer or other suitable dryer, and then, calcined. The obtained ferrite powders are dispersed in a solvent and the ceramic slurry is adjusted. Then, molding is performed using the ceramic slurry by a doctor-blade method to obtain a long ceramic green sheet. A ceramic green sheet of a fixed size is stamped out from the long ceramic sheet and, as required, holes for via holes are formed, and thus a ceramic green sheet 2 is produced.

Next, coil conductor patterns 3 to 7 and lead-out electrodes 8 and 9 are formed on each ceramic green sheet 2 by a screen-printing method, and simultaneously, a conductive paste is filled in the holes to form via holes 15. A direction of squeegee travel is as shown in FIG. 2 with reference to the coil conductor pattern, for example. At this time, the coil conductor patterns 3 to 7, are printed and simultaneously the via holes 15 are formed on the ceramic green sheets 2 having the holes for via hole formed therein while the ceramic green sheets are not backed with a carrier film.

That is, on the surface of the ceramic green sheet 2 shown in FIG. 2, a first land 4a is printed using a conductive paste so as to cover the hole for the via hole, and simultaneously, the conductive paste is filled in the hole for the via hole. Accordingly, the coil conductor pattern 4 includes a first land 4a having the via hole 15 for connection between layers and a second land 4b connected to the via hole 15. Then, the second land 4b is made larger in diameter than the first land 4a.

That is, the coil conductor patterns 3 to 7 includes first lands 3a to 6a having the via holes 15 for connection between layers and second lands 4b to 7b connected to the via holes 15. Then, the second lands 4b to 7b are larger in diameter than the first lands 3a to 7a.

Furthermore, the lead-out portion of the coil conductor pattern 3 is connected to the lead-out electrode 8 formed on the left side of the sheet 2. The lead-out portion of the coil conductor pattern 7 is connected to the lead-out electrode 9 formed on the right side of the sheet 2.

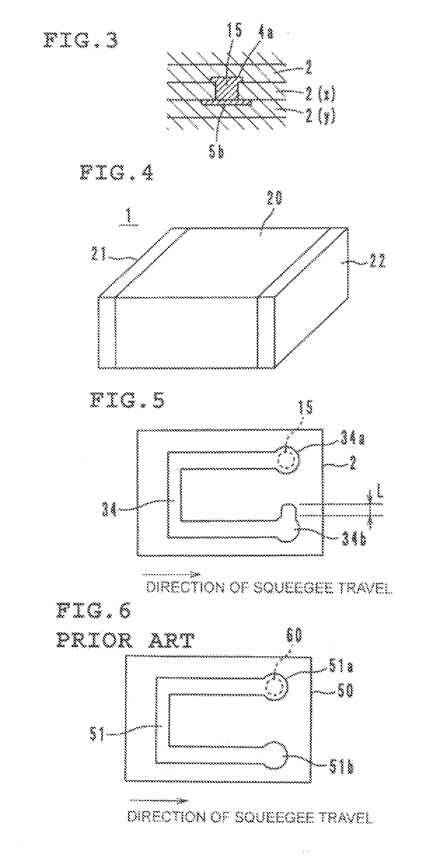

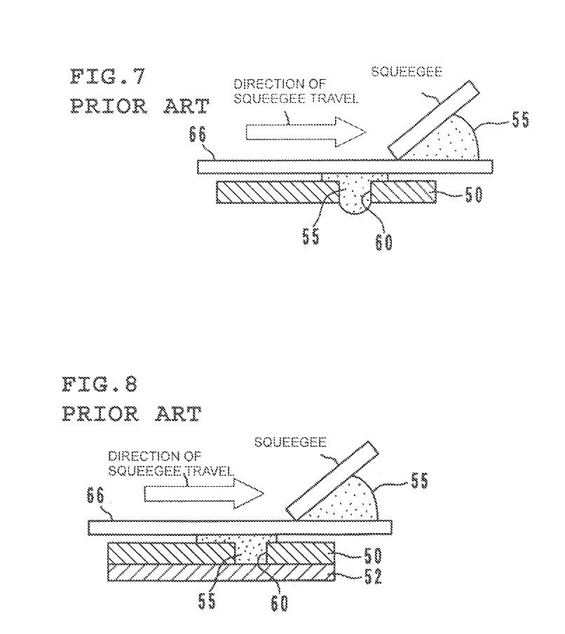

Each ceramic green sheet 2 is laminated and the external ceramic green sheets 2a are disposed on the top and bottom of the laminated green sheets 2. Then, ceramic green sheets 2 and the top and bottom ceramic green sheets 2a are pressed at about 1,000 kgf/cm² to form a laminated block. In this way, the coil conductor patterns 3 to 7 are electrically connected by the via holes 15 and a spiral coil is formed. As shown as one example in FIG. 3, the connection of the conductor patterns is performed such a first land 4a in a sheet 2(x) and a second land 5b in a lower sheet 2(y) are electrically connected through a via hole 15.

After the above-described laminated block has been cut to a fixed size, the laminated block is degreased and integrally burned at about 870° C. Thus, a laminate 20 shown in FIG. 4 is produced.

Next, external electrodes 21 and 22 are formed such that a conductive paste is applied to both end portions of the laminate 20 and baked at about 850° C. The external electrode 21 is electrically connected to the lead-out electrode 8 and the external electrode 22 is electrically connected to the lead-out electrode 9.

In the laminated inductor 1 having the above-described structure, since the shape of the second lands 4b, 5b, 6b, and 7b connected to the via holes 15 in which thin spots easily occur during screen printing is enlarged, the discharge amount of conductive paste for forming the second lands 4b to 7b increases. Accordingly, even if the fill amount of conductive paste to the holes for the via hole is appropriately set in accordance with the first lands 3a to 6a formed at the locations having the hole for the via hole is formed, thin spots are not likely to occur in the second lands 4b to 7b. That is, the appropriate filling of the via holes 15 and the prevention of thin spots in the second lands 4b to 7b are simultaneously achieved. As a result, a laminated inductor 1 having outstanding reliability and productivity is obtained.

Table 1 shows the evaluation result of the laminated inductor 1 (first preferred embodiment). The diameter of the via holes is about 160 μm, the diameter of the first lands 3a, 4a, 5a, and 6a is about 200 μm, and the diameter of the second lands 4b, 5b, 6b, and 7b is about 240 μm, for example. For comparison, in Table 1, the results of the related laminated inductors having the coil conductor pattern 51 shown in FIG. 6 is also provided. In the related laminated inductors, the first land 51a having the via hole 60 and the second land 51b connected to the via hole 60 each are about 200 μm in diameter (Comparative example 1) and are also set to be about 240 μm in diameter (Comparative example 2). The inductance value is an average value of 30 samples and the number rejected in an electrostatic discharge test is shown when a contact discharge is performed by applying a voltage of ±30 kV, ten times for each voltage, at an interval of 0.1 sec to the 30 samples by using an electrostatic discharge gun. The maximum lamination slippage is obtained by magnifying the vertical section of the laminated inductor using a microscope and performing the structural analysis thereof.

TABLE 1

| | | | Evaluation result | | |
|---|---|---|---|---|---|
| | | | | Electrostatic | |
| | Coil conductor | | | discharge | |
| | pattern | | Induc- | test | Maximum |
| | Second | First | tance | Rejection | lamination |
| | land | land | value | number | slippage |
| Preferred | 240 μm | 200 μm | 9.8 μH | 0/30 | 15 μm |
| Embodiment 1 | | | | | |
| Comparative | 200 μm | 200 μm | 10.3 μH | 2/30 | 14 μm |
| example 1 | | | | | |
| Comparative | 240 μm | 240 μm | 9.5 μH | 0/30 | 55 μm |
| example 2 | | | | | |

When the cause of the rejection in the electrostatic discharge test of Comparative example 1 was investigated, it was determined that the rejection resulted from printing defects (printing thin spots) of the second land 51b. Furthermore, when the cause of the increased lamination slippage in Comparative example 2 was investigated, it was found that, since the fill amount of conductive paste in the hole for via hole was too much during printing and the conductive paste protruded from the back surface of the ceramic green sheet, the lamination slippage occurred.

Furthermore, as shown in FIG. 5, a coil conductor pattern 34 in which a second land 34b is substantially equal in diameter to a first land 34a and the second land 34b is extended from a projection plane of the first land to a projection plane of the coil conductor pattern may be used. In this way, the shape of the top view of a spiral coil formed by the coil conductor patterns is equal to the spiral coil of the related laminated inductor and, since the inner area of the coil does not change, the inductance value and the high-frequency characteristics do not change.

Table 2 shows the evaluation result of a laminated inductor having the coil conductor pattern 34 shown in FIG. 5 (preferred embodiment 2). Here, the second land 34b is equal in diameter to the first land 34a, and the second land 34b is lengthened in the amount of L equal to about 100 μm from a projection plane of the first land to a projection plane of the coil conductor pattern (that is, in a direction where the extended portion is hidden when projection is performed in the lamination direction). In this evaluation experiment, a conductive paste having a coefficient of viscosity of about 100 Pa·s is screen printed using a printing plate having an opening ratio of about 60%.

For comparison, in Table 2, the evaluation result of the laminated inductor 1 having the coil conductor pattern 4 shown in FIG. 2 (the above-described preferred embodiment 1) and the evaluation result of the related laminated inductor having the coil conductor pattern 51 shown in FIG. 6 (the above-described Comparative 1) are provided.

TABLE 2

| | | | Evaluation result | | |
|---|---|---|---|---|---|
| | | | | Electrostatic | |
| | Coil conductor | | | discharge | |
| | pattern | | Induc- | test | Maximum |
| | Second | First | tance | Rejection | lamination |
| | land | land | value | number | slippage |
| Preferred | 100 μm* | 200 μm | 10.2 μH | 0/30 | 15 μm |
| Embodiment 2 | | | | | |
| Preferred | 240 μm | 200 μm | 9.8 μH | 0/30 | 15 μm |
| Embodiment 1 | | | | | |
| Comparative | 200 μm | 200 μm | 10.3 μH | 2/30 | 14 μm |
| example 1 | | | | | |

*100 μm extended in a direction where the extended portion is hidden at projection in the lamination direction

In the case of the laminated inductor 1 of the first preferred embodiment, since the diameter of the second lands 4b to 7b is increased, the area inside the coil is reduced and the inductance value is slightly lowered as compared to the related inductor. However, the inductance value of the laminated inductor of the second preferred embodiment is not substantially changed.

Next, Table 3 shows the evaluation result of test samples 1 to 7 in which the diameter (area) of the first land and the second land each are changed. The content of the evaluation test is the same as that in the above-described Tables 1 and 2. The test samples 1 to 5 are prototyped such that, although the diameter of the first land is about 200 μm, the diameter of the second land is changed so as to be about 205, about 210, about 220, about 300, and about 320 μm. The test samples 2 to 4 are accepted in the electrostatic discharge test, their inductance value is also desirable, and their lamination slippage is small. On the other hand, in the test sample 1 (the area ratio is about 1.05), some showed printing defects (printing thin spots) and were rejected. In the test sample 5 (the area ratio is about 2.56), the second land was made larger and the inductance value was lowered.

Furthermore, the test samples 6 and 7 were prototyped such that, although the diameter of the second land was about 220 μm, the diameter of the first land was changed so as to be about 210 and about 215 μm. The evaluation results of the test sample 6 were desirable. However, in test sample 7, the fill amount of conductive paste in the hole for via hole formed in the first land was too much and the lamination slippage increased.

TABLE 3

| | Coil conductor pattern | | | | | Evaluation result | | |
|---|---|---|---|---|---|---|---|---|
| | | | | | Area ratio | | Electrostatic | |
| | | | | | (Second | | discharge test | Maximum |
| Test | Second land | | First land | | land/First | Inductance | Rejection | lamination |
| sample | Diameter | Area | Diameter | Area | land) | value | number | slippage |
| 1* | 205 μm | 33006 μm² | 200 μm | 31416 μm² | 1.05 | 10.4 μH | 1/30 | 14 μm |
| 2 | 210 μm | 34636 μm² | 200 μm | 31416 μm² | 1.10 | 10.2 μH | 0/30 | 16 μm |
| 3 | 220 μm | 38013 μm² | 200 μm | 31416 μm² | 1.21 | 10.1 μH | 0/30 | 15 μm |
| 4 | 300 μm | 70686 μm² | 200 μm | 31416 μm² | 2.25 | 9.5 μH | 0/30 | 15 μm |
| 5* | 320 μm | 80425 μm² | 200 μm | 31416 μm² | 2.56 | 9.2 μH | 0/30 | 15 μm |
| 6 | 220 μm | 38013 μm² | 210 μm | 34636 μm² | 1.10 | 10.1 μH | 0/30 | 16 μm |
| 7* | 220 μm | 38013 μm² | 215 μm | 36305 μm² | 1.05 | 10.1 μH | 0/30 | 35 μm |

Moreover, the present invention is not limited to the above-described preferred embodiments, and it is to be understood that changes and modifications may be made without departing from the spirit or scope of the present invention.

As described above, the present invention is useful for a laminated ceramic electronic component such as an inductor and an impedance element, and a manufacturing method therefor, and in particular, the present invention is outstanding in that, without including a carrier film on the back surface of a ceramic green sheet, appropriate filling of a via hole and the prevention of thin spots in a land are achieved.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-7. (canceled)

8. A laminated ceramic electronic component comprising:
a plurality of ceramic sheets, each including an internal conductor pattern having a first land at one end of the internal conductor pattern and a second land at the other end and having a via hole provided therein, the plurality of ceramic sheets being laminated to define a laminate; wherein
the via hole is filled with a conductive material;
the internal conductor patterns disposed on different ones of the plurality of ceramic sheets are electrically connected to each other through the via hole;
the first land is arranged so as to cover the via hole and the first land provided in one of the plurality of ceramic sheets is electrically connected to the second land provided in another of the plurality of ceramic sheets through the via hole provided in the one ceramic sheet; and
the second land is larger than the first land.

9. The laminated ceramic electronic component according to claim 8, wherein the second land extends from a projection plane of the first land to a projection plane of the coil conductor pattern.

10. The laminated ceramic electronic component according to claim 8, wherein the area of the second land is about 1.10 to about 2.25 times as wide as the area of the first land.

11. The laminated ceramic electronic component according to claim 8, wherein the internal conductors included on the plurality of ceramic sheets define a spiral coil.

12. The laminated ceramic electronic component according to claim 11, wherein terminal ends of the spiral coil define lead-out electrodes.

13. The laminated ceramic electronic component according to claim 11, further comprising two additional ceramic sheets which do not include any internal conductors disposed therein, one of the two additional ceramic sheets being disposed on an upper surface of the laminate, and the other of the two additional ceramic sheets being disposed on a lower surface of the laminate.

14. A manufacturing method for a laminated ceramic electronic component, comprising the steps of:
printing an internal conductor pattern having a first land at one end of the internal conductor pattern and a second land at the other end on the surface of a ceramic sheet having a hole for a via hole formed therein by using a conductive material such that the first land covers the hole for via hole;
filling the conductive material in the hole for the via hole; and
laminating a plurality of ceramic sheets such that the first land in one of the plurality of ceramic sheets is electrically connected to the second land in another of the plurality of ceramic sheets through the via hole formed in the one of the plurality of ceramic sheets to obtain a laminate; wherein
the second land is larger than the first land.

15. The manufacturing method for a laminated ceramic electronic component according to claim 14, wherein the second land extends from a projection plane of the first land to a projection plane of the coil conductor pattern.

16. The manufacturing method for a laminated ceramic electronic component according to claim 14, wherein the area of the second land is about 1.10 to about 2.25 times as wide as the area of the first land.

17. The manufacturing method for a laminated ceramic electronic component according to claim 14, wherein the internal conductor pattern is printed on a ceramic sheet having the hole for the via hole formed therein and the hole for the via hole is filled with a conductive material, without providing a carrier film on a back surface of the ceramic sheet.

18. The manufacturing method for a laminated ceramic electronic component according to claim 14, further comprising the step of:
arranging the internal conductors on the plurality of ceramic sheets so as to define a spiral coil.

19. The manufacturing method for a laminated ceramic electronic component according to claim 14, wherein terminal ends of the spiral coil define lead-out electrodes.

20. The manufacturing method for a laminated ceramic electronic component according to claim 14, further comprising the steps of:
providing two additional ceramic sheets which do not include any internal conductors printed therein;
disposing one of the two additional ceramic sheets on an upper surface of the laminate; and
disposing the other of the two additional ceramic sheets on a lower surface of the laminate.
